(19) United States
(12) Patent Application Publication
(10) Pub. No.: US 2024/0105770 A1
(43) Pub. Date: Mar. 28, 2024

(54) NECKED RIBBON FOR BETTER N WORKFUNCTION FILLING AND DEVICE PERFORMANCE

(71) Applicant: Intel Corporation, Santa Clara, CA (US)

(72) Inventors: Tao CHU, Portland, OR (US); Guowei XU, Portland, OR (US); Chia-Ching LIN, Portland, OR (US); Minwoo JANG, Portland, OR (US); Feng ZHANG, Hillsboro, OR (US); Ting-Hsiang HUNG, Beaverton, OR (US)

(21) Appl. No.: 17/954,291

(22) Filed: Sep. 27, 2022

(51) Int. Cl. H01L 29/06; H01L 21/8234; H01L 29/778; H01L 29/786

(52) U.S. Cl. CPC H01L 29/0673; H01L 21/823412; H01L 29/778; H01L 29/78696

(57) ABSTRACT

Embodiments disclosed herein include transistors and methods of forming transistors. In an embodiment, a transistor comprises a source, a drain, and a pair of spacers between the source and the drain. In an embodiment, a semiconductor channel is between the source and the drain, where the semiconductor channel passes through the pair of spacers. In an embodiment, the semiconductor channel has a first thickness within the pair of spacers and a second thickness between the pair of spacers, where the second thickness is less than the first thickness. In an embodiment, the transistor further comprises a gate stack over the semiconductor channel between the pair of spacers.

### TECHNICAL FIELD

Embodiments of the disclosure are in the field of semiconductor structures and processing and, in particular, to nanoribbon transistor architectures with necked nanoribbons for better workfunction metal filling and device performance.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1A is a cross-sectional illustration of a transistor with nanoribbon semiconductor channels, in accordance with an embodiment.

FIG. 1B is a cross-sectional illustration of the transistor in FIG. 1A along a plane parallel to a direction of the gate stack, in accordance with an embodiment.

FIG. 2A is a cross-sectional illustration of a transistor with nanoribbon semiconductor channels that are necked to form a dumbbell shape, in accordance with an embodiment.

FIG. 2B is a cross-sectional illustration of the transistor in FIG. 2A along a plane parallel to a direction of the gate stack, in accordance with an embodiment.

FIG. 3 is a cross-sectional illustration of an integrated circuit structure that comprises a pair of transistors with semiconductor channels that are optimized for improved gate metal filling between neighboring semiconductor channels, in accordance with an embodiment.

FIG. 4A-4H are cross-sectional illustrations depicting a process for forming a transistor with nanoribbon channels that are necked to form a dumbbell shape, in accordance with an embodiment.

FIG. 5 illustrates a computing device in accordance with one implementation of an embodiment of the disclosure.

FIG. 6 illustrates an interposer that includes one or more embodiments of the disclosure.

### DESCRIPTION OF THE EMBODIMENTS

Embodiments described herein comprise nanoribbon transistor architectures with necked nanoribbons for better workfunction metal filling and device performance. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

To provide context, advanced transistor scaling architectures have begun using nanoribbon-based channels. A nanoribbon is a structure that has a confined dimension (typically thickness) that is one to several nm thick. Nanowire-based structures may also be used, and a nanowire is a structure that has a pair of confined dimensions. However, in many processes used to form nanoribbon-based or nanowire-based channels, the channels have a cross-section (when viewed parallel to the gate stack) that has a non-uniform thickness. Particularly, ends of the channels are thicker than a middle of the channel. This may negatively impact subsequent processing operations, such as workfunction metal deposition. For example, the ends of the channels may pinch together and make it more difficult to deposit the workfunction metal between neighboring channels. This can ultimately result in the formation of voids.

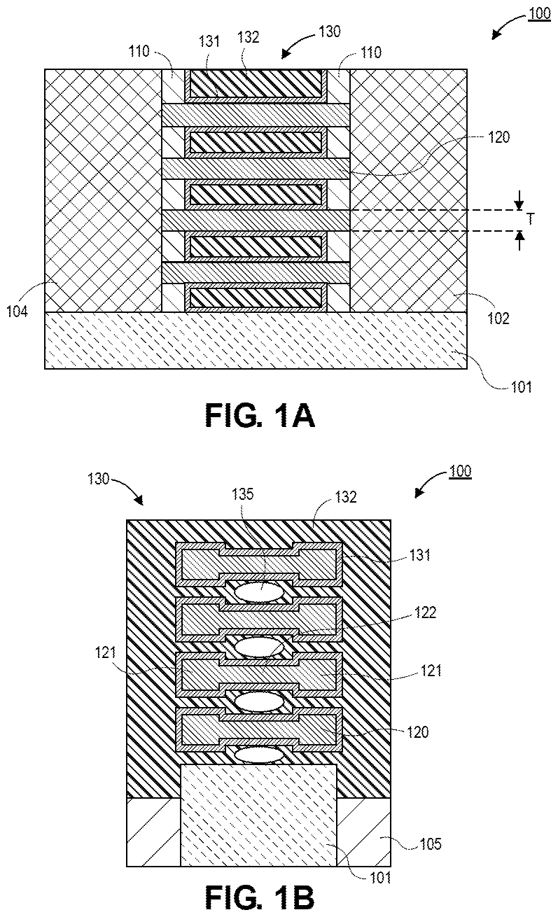

An example of such an existing transistor 100 structure is shown in FIGS. 1A and 1B. FIG. 1A is a cross-section orthogonal to the gate stack 130. As shown in FIG. 1A, the transistor 100 may be formed over a semiconductor substrate 101. The substrate 101 may be a semiconductor fin. A source 102 and a drain 104 may be provided over the substrate 101. The source 102 and the drain 104 may have a pair of spacers 110 between them. Within the spacers 110 is a channel region. The channel region comprises a stack of nanoribbon channels 120. The gate stack 130 is provided around the nanoribbon channels 120. The gate stack 130 may comprise a gate dielectric 131 and a gate metal 132, such as a workfunction metal. As shown, the nanoribbon channels 120 pass through the spacers 110 in order to contact the source 102 and the drain 104. The nanoribbon channels 120 may have a thickness T. The thickness T may be substantially uniform through a length of the nanoribbon channels 120.

FIG. 1B is a cross-sectional illustration of the transistor 100 in a plane parallel to the gate stack 130. The substrate 101 may be a fin that is surrounded by an insulating layer 105, such as an oxide or the like. As shown, the channels 120 may have a non-uniform cross-section. That is, the ends 121 of the channels 120 may be thicker than centers 122 of the channels 120. This structure may result in difficulties in depositing the workfunction metal 132. As such, voids 135 may be formed between the channels 120. The voids negatively impact the performance of the transistor 100, and should ideally be minimized or avoided all together.

Accordingly, embodiments disclosed herein include an additional etching process that reduces the thickness of the ends of the channels 120 (when viewed in a plane parallel to the gate stack). That is, the portion of the channels 120 surrounded by the gate stack may have a center that is thicker than ends of the channels 120. For example, the cross-sectional shape of the channels 120 may be generally described as having an oval like shape with a width of the channel that is greater than a thickness of the channel. The etching process may also result in a necking structure of the channels 120. Particularly, the portion of the channels that passes through the spacers is protected from the etching process. As such, the portions of the channels that pass through the spacers may be thicker than a center portion of the channels. In addition to providing improved workfunction metal deposition, the reduction in thickness of the channels may also improve short channel effects of the transistor.

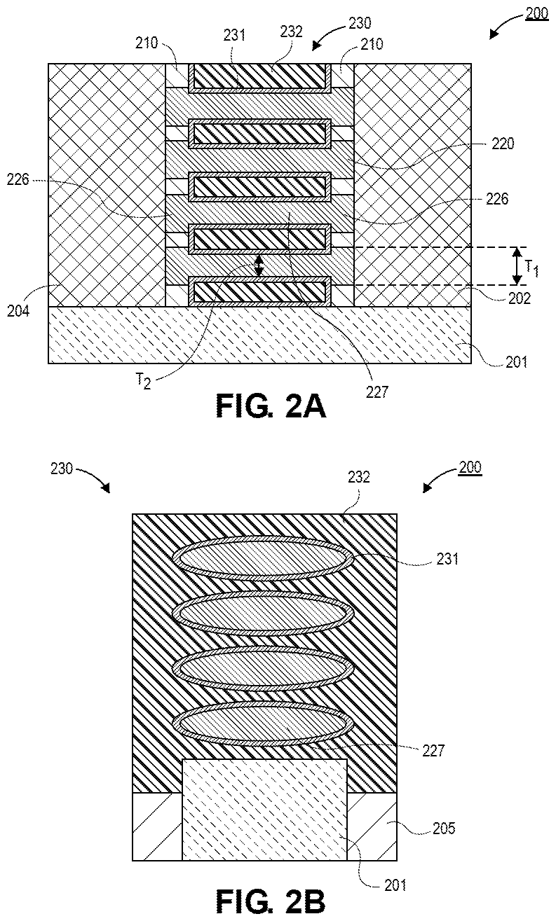

Referring now to FIGS. 2A and 2B, cross-sectional illustrations of a transistor 200 are shown, in accordance with an embodiment. In an embodiment, FIG. 2A is a cross-sectional illustration along a plane that is orthogonal to the direction of the gate stack 230. FIG. 2B is a cross-sectional illustration along a plane that is parallel to the direction of the gate stack 230. In an embodiment, the transistor 200 may be provided over a semiconductor substrate 201. The semiconductor substrate 201 may be a fin in some embodiments. For example, insulating material 205 (e.g., an oxide comprising silicon and oxygen) may be provided around the semiconductor substrate 201. In an embodiment, the semiconductor substrate 201 may comprise silicon or any other suitable semiconductor material. The semiconductor substrate 201 may extend up from a semiconductor wafer or the like.

In an embodiment, the transistor 200 may comprise a source 202 and a drain 204. The source 202 and the drain 204 may comprise semiconductor material. In a particular embodiment, the source 202 and the drain 204 may be epitaxially grown semiconductor material. The epitaxial semiconductor may be in-situ doped in order to provide the necessary doping for the source 202 and the drain 204. Alternatively, any suitable doping process may be used to form the source 202 and the drain 204.

In an embodiment, the surfaces of the source 202 and the drain 204 that face each other may be lined with spacers 210. The spacers 210 may comprise an insulating material, such as an oxide (e.g., comprising silicon and oxygen) or a nitride (e.g., comprising silicon and nitrogen). The region of the transistor 200 between the spacers 210 may be considered the channel region of the transistor 200. The channel region may comprise semiconductor channels 220 that are surrounded by a gate stack 230. The gate stack 230 may comprise a gate dielectric 231 and a gate metal 232 (e.g., a workfunction metal).

The gate dielectric 232 may be, for example, any suitable oxide such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

When the gate metal 232 will serve as an N-type workfunction metal, the gate metal 232 preferably has a workfunction that is between about 3.9 eV and about 4.2 eV. N-type materials that may be used to form the gate metal 232 include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the gate metal 232 will serve as a P-type workfunction metal, the gate metal 232 preferably has a workfunction that is between about 4.9 eV and about 5.2 eV. P-type materials that may be used to form the gate metal 232 include, but are not limited to, ruthenium, palladium, platinum, cobalt, nickel, and conductive metal oxides, e.g., ruthenium oxide. In an embodiment, the gate metal 232 may also comprise a fill metal that is disposed over the workfunction metal.

In an embodiment, the semiconductor channels 220 may pass through the spacers 210 in order to contact the source 202 and the drain 204. Ends 226 of the semiconductor channels 220 may be provided within the spacers 210, and a center 227 of the semiconductor channels 220 may pass through the gate stack 230. In an embodiment, the ends 226 of the semiconductor channels 220 may have first thicknesses T₁ and the center 227 of the semiconductor channels 220 may have a second thickness Ta. The second thickness T₂ may be smaller than the first thickness T₁. For example, the first thickness T₁ may be approximately 1 nm greater than the second thickness Ta. Though, larger or smaller differences between the first thickness T₁ and the second thickness T₂ may occur in some transistor 200 architectures. As used herein, “approximately” may refer to a range of values within ten percent of the stated value. For example, approximately 1 nm may refer to a range between 0.9 nm and 1.1 nm. The cross-sectional shape of the semiconductor channels 220 may sometimes be referred to as having a dumbbell shape. The difference in the thicknesses may be caused by the use of an etching process, as will be described in greater detail below. The reduction in the thickness of the center 227 of the channels 220 also improves short channel effects of the transistor 200.

In an embodiment, the semiconductor channels 220 may be any suitable semiconductor material. In a particular embodiment, the semiconductor channels 220 may comprise silicon. Though, other semiconductor materials may be used for the semiconductor channels 220 (e.g., germanium, silicon germanium, Group III-V semiconductors, or the like). In an embodiment, the semiconductor channels 220 may be lined around their perimeter with the gate dielectric 231 and the gate metal 232. As such, the semiconductor channels 220 may sometimes be referred to as gate-all-around (GAA) channels.

As shown in FIG. 2B, the cross-sectional shape of the semiconductor channels 220 through the center 227 that is surrounded by the gate stack 230 may be non-rectangular. In a particular embodiment, the center 227 of the semiconductor channels 220 may have a cross-section with ends that are thinner than a center of the semiconductor channels 220. In some instances, the center 227 of the semiconductor channels 220 may be referred to as having an oval shaped cross-section (when viewed in a plane that runs parallel to the direction of the gate stack 230). The shape of the center 227 of the semiconductor channels 220 allows for better filling of the gate metal 232. Particularly, since there are no choke points (as shown in FIG. 1B), the formation of voids between neighboring semiconductor channels 220 is minimized or eliminated.

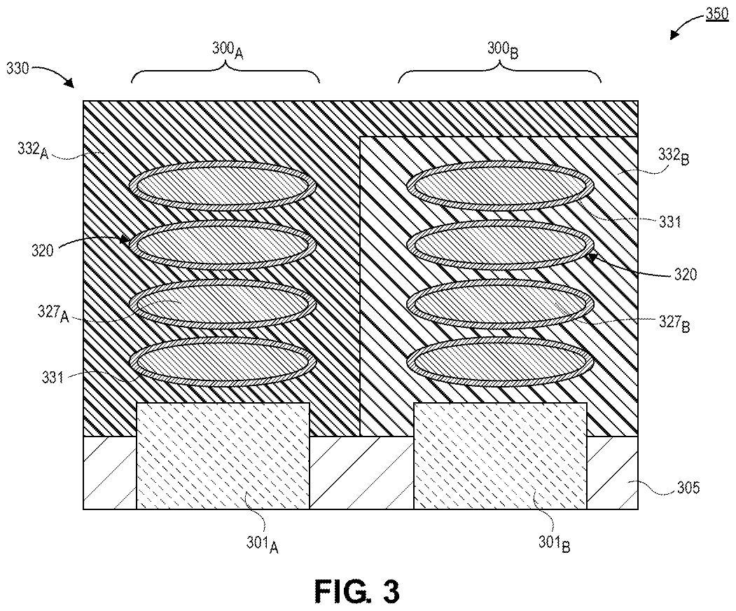

Referring now to FIG. 3, a cross-sectional illustration of an integrated circuit structure 350 is shown, in accordance with an embodiment. The plane shown in FIG. 3 is a plane that runs parallel to the direction of the gate stack 330. As shown, the integrated circuit structure 350 may comprise a first transistor 300A and a second transistor 300B. The first transistor 300A may be formed over a first fin 301A, and the second transistor 300B may be formed over a second fin 301B. Insulating layer 305 may surround the fins 301A and 301B.

The first transistor 300A may comprise a vertical stack of semiconductor channels 320. The centers 327A of the semiconductor channels 320 are shown in FIG. 3. The center 327A may be a region of the semiconductor channels 320 between spacers (not visible in the plane shown in FIG. 3). The center 327A may be surrounded by the gate stack 330. Particularly, for the first transistor 300A, a gate dielectric 331 and a first gate metal 332A surround the semiconductor channel 320. Similar to the embodiments described above, the centers 327A may have a non-rectangular cross-section with edges that are thinner than a middle of the center 327A of the semiconductor channels 320.

The second transistor 300B may comprise a vertical stack of semiconductor channels 320. The centers 327B of the semiconductor channels 320 are shown in FIG. 3. The center 327B may be a region of the semiconductor channels 320 between spacers (not visible in the plane shown in FIG. 3). The center 327B may be surrounded by the gate stack 330. Particularly, for the second transistor 300B, a gate dielectric 331 and a second gate metal 332B surround the semiconductor channel 320. Similar to the embodiments described above, the centers 327B may have a non-rectangular cross-section with edges that are thinner than a middle of the center 327B of the semiconductor channels 320.

As shown in FIG. 3, the first gate metal 332A may be different than the second gate metal 332B. For example, the first gate metal 332A may be a P-type workfunction metal, and the second gate metal 332B may be an N-type workfunction metal. Accordingly, the gate stack 330 may couple together a P-type transistor 300A and an N-type transistor 300B.

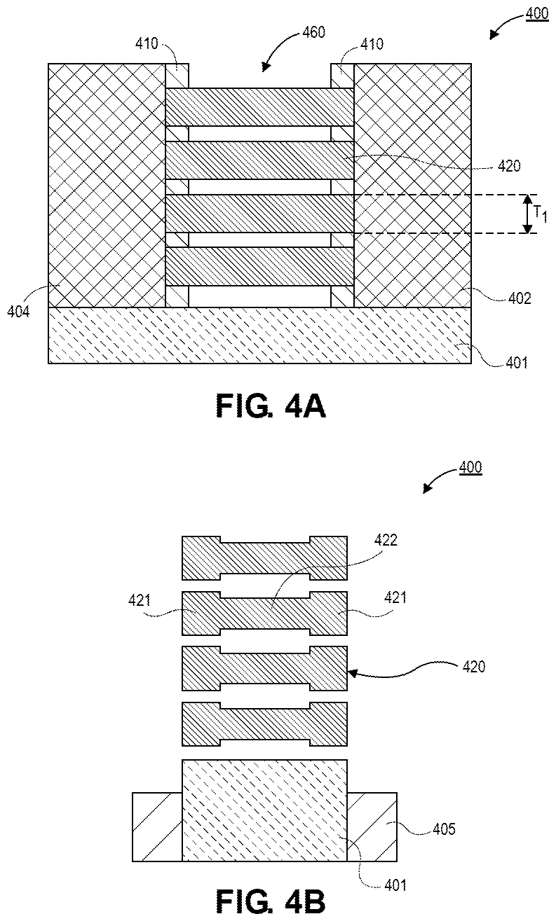

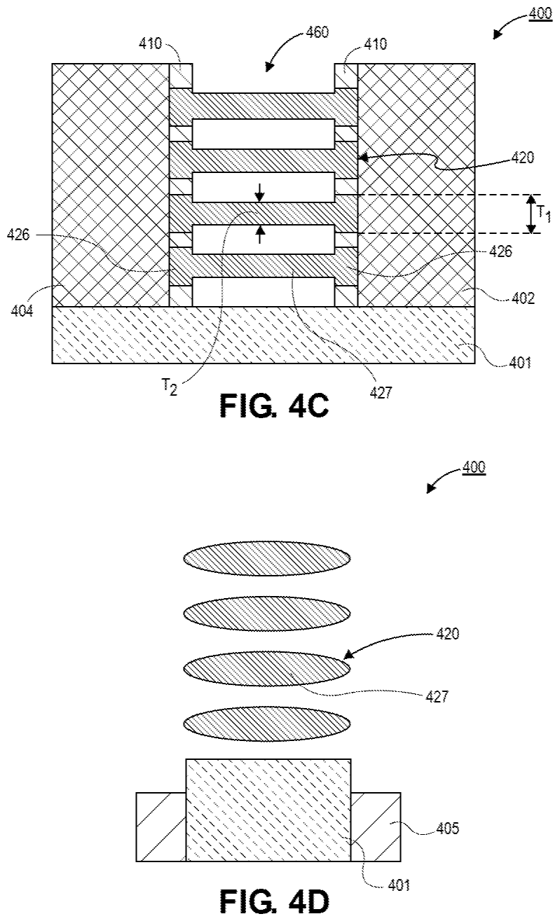

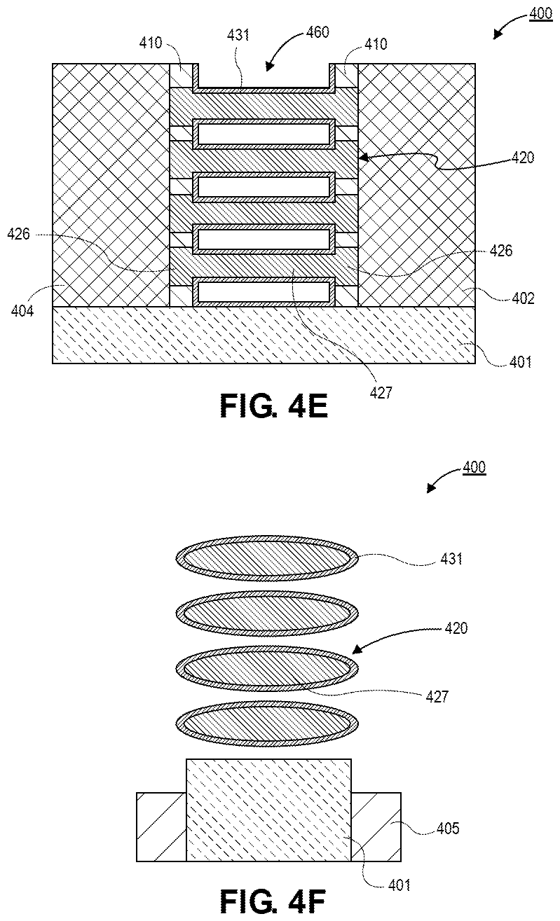

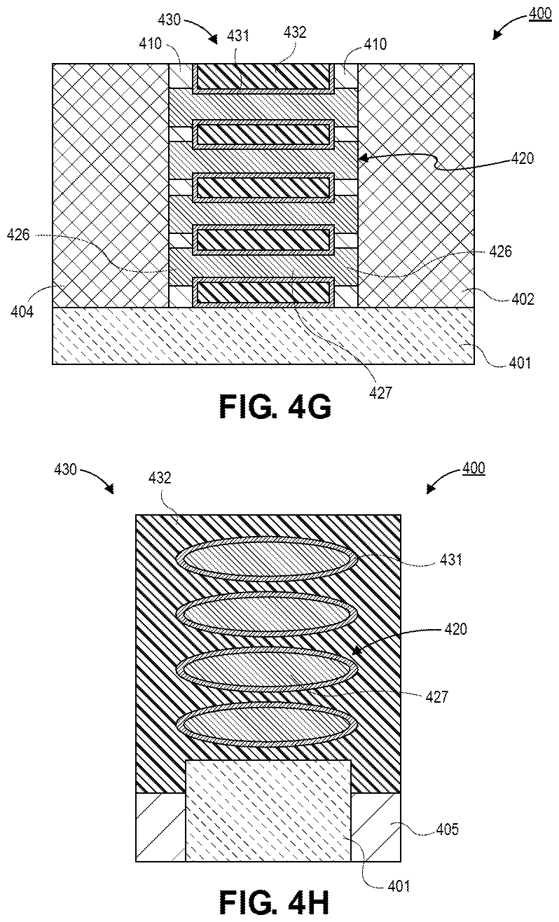

Referring now to FIGS. 4A-4H, a series of cross-sectional illustrations depicting a process for forming a transistor 400 with improved workfunction metal filling is shown, in accordance with an embodiment. In an embodiment, the transistor 400 may be fabricated with existing processing operations up to the opening of the channel region (e.g., removing a sacrificial gate material).

Referring now to FIGS. 4A and 4B, a pair of cross-sectional illustrations depicting a transistor 400 at a stage of manufacture is shown, in accordance with an embodiment. FIG. 4A is a cross-section along a plane that is orthogonal to the direction of the gate stack, and FIG. 4B is a cross-section along a plane that is parallel to the direction of the gate stack. As shown in FIG. 4A, the transistor 400 comprises a substrate 401, such as a semiconductor fin or the like. An insulating layer 405 may surround the substrate 401, as shown in FIG. 4B.

A source 402 and a drain 404 are formed over the substrate 401. The source 402 and the drain 404 may be formed with any suitable materials and processes typical of gate-all-around transistor fabrication. In an embodiment, a pair of spacers 410 are provided between the source 402 and the drain 404. A cavity 460 may be provided between the spacers 410. The cavity 460 is the region that was previously filled with a sacrificial gate stack.

Removal of the sacrificial gate stack reveals portions of the semiconductor channels 420. The semiconductor channels 420 may have a first thickness T₁. The first thickness T₁ may be substantially uniform across a length of the semiconductor channels 420. In an embodiment, the semiconductor channels 420 may be nanowire channels, nanoribbon channels, nanosheet channels, or the like. A stack of four semiconductor channels 420 is shown in FIGS. 4A and 4B. Though, it is to be appreciated that one or more semiconductor channels 420 may be used in the transistor 400.

As shown in FIG. 4B, the cross-section of the transistor parallel to the direction of the gate stack may include semiconductor channels 420 that have a non-uniform thickness. For example, ends 421 of the semiconductor channels 420 may be thicker than a middle region 422 of the semiconductor channels 420. The thicker ends 421 may result in difficulties during deposition of the gate metal. Accordingly, the shape of the semiconductor channels 420 may need to be modified, as will be described in greater detail below.

Referring now to FIGS. 4C and 4D, a pair of cross-sectional illustrations depicting the transistor 400 after an etching process is shown, in accordance with an embodiment. FIG. 4C is a cross-section along a plane that is orthogonal to the direction of the gate stack, and FIG. 4D is a cross-section along a plane that is parallel to the direction of the gate stack. As shown, an etchant is used to recess the thickness of the semiconductor channels 420. As shown in FIG. 4C, the semiconductor channels include ends 426 within the spacers 410 that have a first thickness T₁ and a center region 427 that has a second thickness T₂ that is smaller than the first thickness T₁. For example, the first thickness T₁ may be approximately 1 nm greater than the second thickness T₂ or more. The etching process may include a DEA etch and/or a DHF etch.

As shown in FIG. 4D, the etching process may result in centers regions 427 of the semiconductor channels 420 having a non-rectangular cross-section. In an embodiment, the cross-section of the center regions 427 may have sides that are thinner than a middle of the center regions 427. In the particular embodiment shown in FIG. 4D, the center regions 427 may have an oval shaped cross-section. As those skilled in the art will appreciate, the edges of the center regions 427 are more exposed to the etching chemistry, and therefore, etch faster than the middle of the center regions 427. In an embodiment, the etching chemistry may be an isotropic etching chemistry. Since the edges are narrower than the middle, subsequent depositions processes (e.g., to deposit the gate metal) are easier to implement and have a reduced risk of forming voids between the semiconductor channels 420.

Referring now to FIGS. 4E and 4F, a pair of cross-sectional illustrations depicting the transistor 400 after the gate dielectric 431 is deposited is shown, in accordance with an embodiment. FIG. 4E is a cross-section along a plane that is orthogonal to the direction of the gate stack, and FIG. 4F is a cross-section along a plane that is parallel to the direction of the gate stack. As shown, the gate dielectric 431 is conformally deposited over surfaces between the spacers 410. This results in the semiconductor channels 420 being completely surrounded by the gate dielectric 431. The gate dielectric 431 may also be formed over the interior surfaces of the spacers 410. The gate dielectric 431 may be a material similar to the gate dielectric materials described in greater detail above. The gate dielectric 431 may be deposited with an atomic layer deposition (ALD) process, a chemical vapor deposition (CVD) process, or the like.

Referring now to FIGS. 4G and 4H, a pair of cross-sectional illustrations depicting the transistor 400 after the gate metal 432 is deposited is shown, in accordance with an embodiment. FIG. 4G is a cross-section along a plane that is orthogonal to the direction of the gate stack, and FIG. 4H is a cross-section along a plane that is parallel to the direction of the gate stack. As shown, the gate metal 432 is provided around the semiconductor channels 420. The gate metal 432 and the gate dielectric 431 may form the gate stack 430 between the spacers 410. In an embodiment, the gate metal 432 may comprise a workfunction metal. Suitable workfunction metals for P-type transistors 400 and N-type transistors 400 are provided above. The gate metal 432 may be deposited with an ALD process, a CVD process, or the like. Particularly, since the ends of the center region 427 are thinner than a middle of the center region 427, deposition of the gate metal 432 may fully fill the space between neighboring semiconductor channels 420 and eliminate the formation of voids. As such, electrical performance of the transistor 400 is improved.

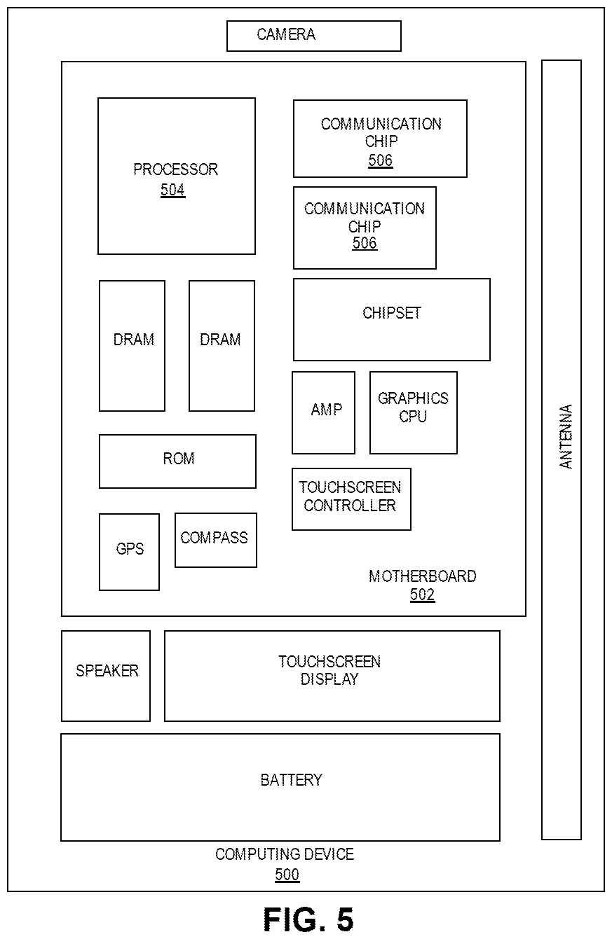

FIG. 5 illustrates a computing device 500 in accordance with one implementation of an embodiment of the present disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. The integrated circuit die of the processor 504 may include one or more structures, such as a transistor with semiconductor channels that are necked to form dumbbell shaped channels between a source and a drain, built in accordance with implementations of embodiments of the present disclosure. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. The integrated circuit die of the communication chip 506 may include one or more structures, such as a transistor with semiconductor channels that are necked to form dumbbell shaped channels between a source and a drain, built in accordance with implementations of embodiments of the present disclosure.

In further implementations, another component housed within the computing device 500 may contain an integrated circuit die that includes one or structures, such as a transistor with semiconductor channels that are necked to form dumbbell shaped channels between a source and a drain, built in accordance with implementations of embodiments of the present disclosure.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

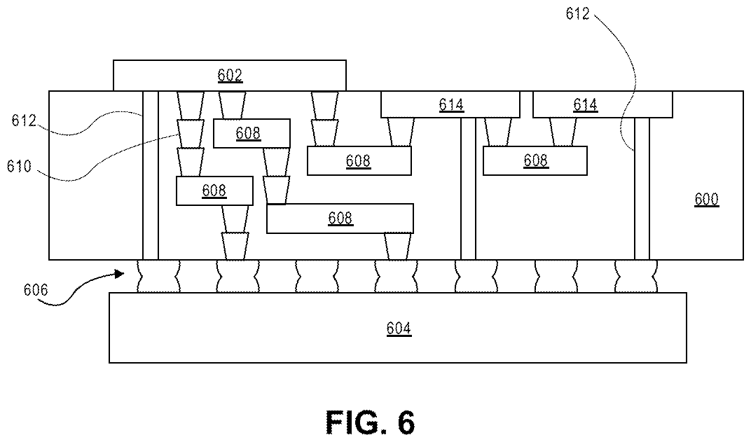

FIG. 6 illustrates an interposer 600 that includes one or more embodiments of the present disclosure. The interposer 600 is an intervening substrate used to bridge a first substrate 602 to a second substrate 604. The first substrate 602 may be, for instance, an integrated circuit die. The second substrate 604 may be, for instance, a memory module, a computer motherboard, or another integrated circuit die. Generally, the purpose of an interposer 600 is to spread a connection to a wider pitch or to reroute a connection to a different connection. For example, an interposer 600 may couple an integrated circuit die to a ball grid array (BGA) 606 that can subsequently be coupled to the second substrate 604. In some embodiments, the first and second substrates 602/604 are attached to opposing sides of the interposer 600. In other embodiments, the first and second substrates 602/604 are attached to the same side of the interposer 600. And in further embodiments, three or more substrates are interconnected by way of the interposer 600.

The interposer 600 may be formed of an epoxy resin, a fiberglass-reinforced epoxy resin, a ceramic material, or a polymer material such as polyimide. In further implementations, the interposer 600 may be formed of alternate rigid or flexible materials that may include the same materials described above for use in a semiconductor substrate, such as silicon, germanium, and other group III-V and group IV materials.

The interposer 600 may include metal interconnects 608 and vias 610, including but not limited to through-silicon vias (TSVs) 612. The interposer 600 may further include embedded devices 614, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 600. In accordance with embodiments of the disclosure, apparatuses or processes disclosed herein may be used in the fabrication of interposer 600 or in the fabrication of components included in the interposer 600.

Thus, embodiments of the present disclosure include integrated circuit structures having a transistor with semiconductor channels that are necked to form dumbbell shaped channels between a source and a drain.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a transistor, comprising: a source; a drain; a pair of spacers between the source and the drain; a semiconductor channel between the source and the drain, where the semiconductor channel passes through the pair of spacers, and wherein the semiconductor channel has a first thickness within the pair of spacers and a second thickness between the pair of spacers, wherein the second thickness is less than the first thickness; and a gate stack over the semiconductor channel between the pair of spacers.

Example 2: the transistor of Example 1, wherein the semiconductor channel is a nanoribbon, a nanowire, or a nanosheet.

Example 3: the transistor of Example 1 or Example 2, wherein the first thickness is approximately 1 nm or more than the second thickness.

Example 4: the transistor of Examples 1-3, wherein the semiconductor channel has an oval shaped cross-section when viewed in a plane parallel to the gate stack.

Example 5: the transistor of Examples 1-4, wherein the gate stack comprises a gate dielectric around the semiconductor channel, and a workfunction metal over the gate dielectric.

Example 6: the transistor of Examples 1-5, further comprising: a plurality of semiconductor channels in a vertical stack between the source and the drain.

Example 7: the transistor of Example 6, wherein the plurality of semiconductor channels comprises at least four semiconductor channels.

Example 8: the transistor of Examples 1-7, wherein the semiconductor channel comprises silicon.

Example 9: the transistor of Examples 1-8, wherein the semiconductor channel is provided above a semiconductor fin.

Example 10: the transistor of Example 9, wherein a width of the semiconductor channel is substantially equal to a width of the semiconductor fin.

Example 11: a semiconductor structure, comprising: a first transistor with a first semiconductor channel; a second transistor with a second semiconductor channel; and a gate stack across the first semiconductor channel and the second semiconductor channel, wherein the gate stack comprises: a first workfunction metal over the first semiconductor channel; and a second workfunction metal over the second semiconductor channel, wherein the first semiconductor channel and the second semiconductor channel comprise a dumbbell shaped cross-section when viewed in a plane orthogonal to the gate stack.

Example 12: the semiconductor structure of Example 11, wherein the first semiconductor channel and the second semiconductor channel are nanoribbons, nanowires, or nanosheets.

Example 13: the semiconductor structure of Example 11 or Example 12, wherein the dumbbell shaped cross-section includes ends with a first thickness and a center with a second thickness that is smaller than the first thickness.

Example 14: the semiconductor structure of Example 13, wherein the first thickness is approximately 1 nm or more than the second thickness.

Example 15: the semiconductor structure of Example 13 or Example 14, wherein the ends of the first semiconductor channel and the second semiconductor channel pass through spacers, wherein the centers of the first semiconductor channel and the second semiconductor channel are between the spacers.

Example 16: the semiconductor structure of Examples 11-15, wherein the first semiconductor channel and the second semiconductor channel include oval shaped cross-sections when viewed in a plane parallel to the gate stack.

Example 17: a method of forming a semiconductor structure, comprising: forming a transistor, comprising: a source; a drain; a pair of spacers between the source and the drain; and a semiconductor channel between the source and the drain that passes through the pair of spacers, wherein the semiconductor channel has a first thickness; etching the semiconductor channel, wherein the etching results in the semiconductor channel having a first thickness within the pair of spacers and a second thickness between the pair of spacers, wherein the second thickness is smaller than the first thickness; and forming a gate stack over the semiconductor channel between the pair of spacers.

Example 18: the method of Example 17, wherein the etching is an isotropic etching process.

Example 19: the method of Example 17 or Example 18, wherein the etching uses a DEA and/or a DHF etching chemistry.

Example 20: the method of Examples 17-19, wherein the semiconductor channel has an oval cross-section when viewed in a plane parallel to the gate stack.

Example 21: the method of Examples 17-20, wherein the gate stack comprises a gate dielectric and a workfunction metal.

Example 22: the method of Examples 17-21, wherein the semiconductor channel is a nanoribbon, a nanowire, or a nanosheet.

Example 23: a computing system, comprising: a board; a component coupled to the board, wherein the component comprises an integrated circuit structure that comprises: a transistor with a semiconductor channel between a source and a drain, wherein the semiconductor channel passes through a pair of spacers, and wherein the semiconductor channel has a first thickness within the pair of spacers and a second thickness between the spacers, wherein the second thickness is less than the first thickness.

Example 24: the computing system of Example 23, further comprising: a memory coupled to the board.

Example 25: the computing system of Example 23 or Example 24, further comprising: a communication chip coupled to the board.

What is claimed is:

1. A transistor, comprising:
a source;
a drain;
a pair of spacers between the source and the drain;
a semiconductor channel between the source and the drain, where the semiconductor channel passes through the pair of spacers, and wherein the semiconductor channel has a first thickness within the pair of spacers and a second thickness between the pair of spacers, wherein the second thickness is less than the first thickness; and
a gate stack over the semiconductor channel between the pair of spacers.

2. The transistor of claim 1, wherein the semiconductor channel is a nanoribbon, a nanowire, or a nanosheet.

3. The transistor of claim 1, wherein the first thickness is approximately 1 nm or more than the second thickness.

4. The transistor of claim 1, wherein the semiconductor channel has an oval shaped cross-section when viewed in a plane parallel to the gate stack.

5. The transistor of claim 1, wherein the gate stack comprises a gate dielectric around the semiconductor channel, and a workfunction metal over the gate dielectric.

6. The transistor of claim 1, further comprising:
a plurality of semiconductor channels in a vertical stack between the source and the drain.

7. The transistor of claim 6, wherein the plurality of semiconductor channels comprises at least four semiconductor channels.

8. The transistor of claim 1, wherein the semiconductor channel comprises silicon.

9. The transistor of claim 1, wherein the semiconductor channel is provided above a semiconductor fin.

10. The transistor of claim 9, wherein a width of the semiconductor channel is substantially equal to a width of the semiconductor fin.

11. A semiconductor structure, comprising:
a first transistor with a first semiconductor channel;
a second transistor with a second semiconductor channel; and
a gate stack across the first semiconductor channel and the second semiconductor channel, wherein the gate stack comprises:
a first workfunction metal over the first semiconductor channel; and
a second workfunction metal over the second semiconductor channel, wherein the first semiconductor channel and the second semiconductor channel comprise a dumbbell shaped cross-section when viewed in a plane orthogonal to the gate stack.

12. The semiconductor structure of claim 11, wherein the first semiconductor channel and the second semiconductor channel are nanoribbons, nanowires, or nanosheets.

13. The semiconductor structure of claim 11, wherein the dumbbell shaped cross-section includes ends with a first thickness and a center with a second thickness that is smaller than the first thickness.

14. The semiconductor structure of claim 13, wherein the first thickness is approximately 1 nm or more than the second thickness.

15. The semiconductor structure of claim 13, wherein the ends of the first semiconductor channel and the second semiconductor channel pass through spacers, wherein the centers of the first semiconductor channel and the second semiconductor channel are between the spacers.

16. The semiconductor structure of claim 11, wherein the first semiconductor channel and the second semiconductor channel include oval shaped cross-sections when viewed in a plane parallel to the gate stack.

17. A method of forming a semiconductor structure, comprising:
forming a transistor, comprising:
a source;
a drain;
a pair of spacers between the source and the drain; and
a semiconductor channel between the source and the drain that passes through the pair of spacers, wherein the semiconductor channel has a first thickness;
etching the semiconductor channel, wherein the etching results in the semiconductor channel having a first thickness within the pair of spacers and a second thickness between the pair of spacers, wherein the second thickness is smaller than the first thickness; and
forming a gate stack over the semiconductor channel between the pair of spacers.

18. The method of claim 17, wherein the etching is an isotropic etching process.

19. The method of claim 17, wherein the etching uses a DEA and/or a DHF etching chemistry.

20. The method of claim 17, wherein the semiconductor channel has an oval cross-section when viewed in a plane parallel to the gate stack.

21. The method of claim 17, wherein the gate stack comprises a gate dielectric and a workfunction metal.

22. The method of claim 17, wherein the semiconductor channel is a nanoribbon, a nanowire, or a nanosheet.

23. A computing system, comprising:
a board;
a component coupled to the board, wherein the component comprises an integrated circuit structure that comprises:
a transistor with a semiconductor channel between a source and a drain, wherein the semiconductor channel passes through a pair of spacers, and wherein the semiconductor channel has a first thickness within the pair of spacers and a second thickness between the spacers, wherein the second thickness is less than the first thickness.

24. The computing system of claim 23, further comprising:
a memory coupled to the board.

25. The computing system of claim 23, further comprising:
a communication chip coupled to the board.
